(19) United States
(12) Patent Application Publication
(10) Pub. No.: US 2024/0237321 A9
(43) Pub. Date: Jul. 11, 2024

(54) METHODS AND APPARATUS FOR USING ROBOTICS TO ASSEMBLE/DE-ASSEMBLE COMPONENTS AND PERFORM SOCKET INSPECTION IN SERVER BOARD MANUFACTURING

(71) Applicant: Intel Corporation, Santa Clara, CA (US)

(72) Inventor: Shoghi Effendi RAJAGOPAL, Kulim (MY)

(73) Assignee: Intel Corporation, Santa Clara, CA (US)

(21) Appl. No.: 17/972,488

(22) Filed: Oct. 24, 2022

(51) Int. Cl. H05K 13/08; H05K 13/04

(52) U.S. Cl. CPC H05K 13/0812; H05K 13/0408; H05K 13/0815

(57) ABSTRACT

The disclosure is directed to apparatus and methods for manufacturing including a collaborative robot, a camera operatively coupled to the collaborative robot, a memory coupled to the collaborative robot, and processing circuitry coupled to the memory, the processing circuitry configured to receive image data of at least one component intended for a printed circuit board (PCB), the image data collected by the camera operatively coupled to the collaborative robot, determine, based on the image data, a coordinate location for the component, and secure the component to the PCB using an end effector of the collaborative robot based on the received image data. In one embodiment, the collaborative robot is configured to operate alongside a human, the collaborative robot in combination with the camera configured to manufacture a computer system with the PCB.

### FIELD OF THE DISCLOSURE

This disclosure generally relates to field of server board manufacturing, and more particularly relates to methods and apparatus for using robotics to assemble and inspect server boards during manufacturing of high count memory slots and server board testing.

### BACKGROUND

Server board manufacturing and assembly currently requires human handling to inspect server boards with high count memory slots and mixed vendor components. Server board testing further involves human handling. Particularly, the critical components on a processing unit require careful handling by humans to avoid failures due to contact and sunken or damaged pins. A damaged pin in this regard includes pins on a memory DIMM on a server board. Human inspections often fail to identify component damage prior to production. What is needed is a system and method that addresses the human interactions that cause test failures and component damages thereby negatively affecting throughput time and efficiency.

### BRIEF DESCRIPTION OF THE DRAWINGS

A detailed description is set forth below with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 illustrates a work station for manufacturing a computer system using a collaborative robot in accordance with an embodiment of the disclosure.

FIG. 2A illustrates an exemplary socket with a plurality of pins for receiving a DIMM showing a sunken pin in accordance with an embodiment of the disclosure.

FIG. 2B illustrates an exemplary socket with a plurality of pins for receiving a DIMM showing foreign matter causing a short in accordance with an embodiment of the disclosure.

FIG. 3 illustrates an exemplary image of a socket taken by a camera in accordance with an embodiment of the disclosure.

FIG. 4 illustrates an exemplary system for manufacturing a computer system using a collaborative robot in accordance with various embodiments of the disclosure.

FIG. 5 illustrates a flow diagram of a method in accordance with an embodiment of the disclosure.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc. in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail. For the purposes of the present document, the phrases “A or B” and “A/B” mean (A), (B), or (A and B).

In terms of a general overview, this disclosure is generally directed to systems and methods for manufacturing a computer system including a server board. For example, in a pick and place (PnP) type manufacturing, components from various sources are combined on a server board to make a computer system. For this reason, humans are required to combine the different-sourced components. Server board testing often involves human handling. Particularly, the critical components on a processing unit require careful handling by humans to avoid failures due to contact and sunken pins. A sunken pin in this regard includes pins on a memory DIMM on a server board. Human inspections often fail to identify component damage prior to production.

What is needed is a system and method that addresses the human interactions that cause test failures and component damages thereby negatively affecting throughput time and efficiency for server board manufacturing.

In one or more embodiments, an apparatus for manufacturing includes a collaborative robot, a camera operatively coupled to the collaborative robot, a memory coupled to the collaborative robot, and processing circuitry coupled to the memory, the processing circuitry configured to receive image data of at least one component intended for a printed circuit board (PCB), the image data collected by the camera operatively coupled to the collaborative robot, determine, based on the image data, a coordinate location for the component, and secure the component to the PCB using an end effector of the collaborative robot based on the received image data. In one embodiment, the collaborative robot is configured to operate alongside a human, the collaborative robot in combination with the camera configured to manufacture a computer system with the PCB.

In one or more embodiments, the processing circuitry directs the collaborative robot to secure the component on the PCB based on the image data, the PCB may be a server board and the component may be one of a plurality vendor-sourced components. In one or more embodiments, the component is a semiconductor memory socket component having pin configuration. In another embodiment, the component is a semiconductor in-line memory module for insertion into sockets on the PCB. In an embodiment, an end effector of the collaborative robot lifts and inserts a semiconductor in-line memory module into each socket, each socket configured to hold dual in-line memory modules (DIMM).

In one or more embodiments, the processing circuitry is further configured to direct inspection of the component for socket pin defects with the camera, the component being a socket comprised of a plurality of pins. In one embodiment, the camera has a pixel resolution of at least 64 megapixels with 0.0025 mm per pixel and three dimensional capabilities.

Another embodiment is directed to a method for manufacturing a server board, including receiving image data for the server board from a camera operatively connected to a collaborative robot, determining, based on the image data, a coordinate location for a plurality of components on the server board, directing a stop of the manufacturing if the image data identifies a pin defect on the server board, and directing the collaborative robot to position the plurality of components on the server board based on the coordinate location using an end effector of the collaborative robot if no pin defects are identified on the server board.

In one or more embodiments, the directing the collaborative robot includes directing the collaborative robot to insert and secure a plurality of sockets onto the server board, and directing the collaborative robot to insert a plurality of memory modules into the plurality of sockets.

In one or more embodiments, the directing includes directing the collaborative robot to use tools and attachments to secure the plurality of components on the server board.

In one of more embodiments the method includes directing the camera to inspect socket pin quality based on received socket pin configuration, performing a comparison to known socket pin locations, and identifying sunken or damaged pin locations based on three dimensional imaging performed by the camera compared to the known socket pin locations. In one embodiment, identifying sunken or damaged pin locations includes directing the collaborative robot to review at least 4000 pins on the server board.

Another embodiment is directed to a collaborative robot system including an end effector coupled to the collaborative robot, a camera system operatively coupled to the collaborative robot, the camera system configured to receive image data of a plurality of components intended for manufacturing a computer system including a printed circuit board (PCB), a plurality of components including at least a plurality of sockets, a plurality of dual in-line memory modules (DIMM), a plurality of attachment components via a plurality of tools for use by the end effector, and a communication interface and processing circuitry configured to receive directions for manufacturing the computer system using the end effector and camera system. In one or more embodiments, the processing circuitry is configured to determine, based on the image data, a coordinate location for the plurality of components, and secure the plurality of components to the PCB using the end effector of the collaborative robot based on the image data. In one or more embodiments, the processing circuitry is configured to perform model differentiation based on the image data via character reading by the camera system, the model differentiation to identify diverse components among the plurality of components.

In one or more embodiments, the processing circuitry is configured to direct inspection of the plurality of components for socket pin defects with the camera system, wherein the plurality of components includes a socket comprised of a plurality of pins based on three dimensional imaging performed by the camera system based on a comparison to stored socket pin locations and identify sunken pin locations based on three dimensional imaging performed by the camera system and a comparison to stored socket pin locations.

Embodiments herein relate to server board manufacturing and assembly using a collaborative robot with a high resolution camera system operatively coupled to the collaborative robot to efficiently manufacture computer systems and prepare the computer systems for transport. Collaborative robots herein include camera systems configured to inspect server boards with high count memory slots and identify mixed vendor components. As part of manufacturing process, prior to preparing a server board, to prevent inoperable server board, embodiments are direct to identifying any sunken pins on a socket prior to receiving a memory DIMM.

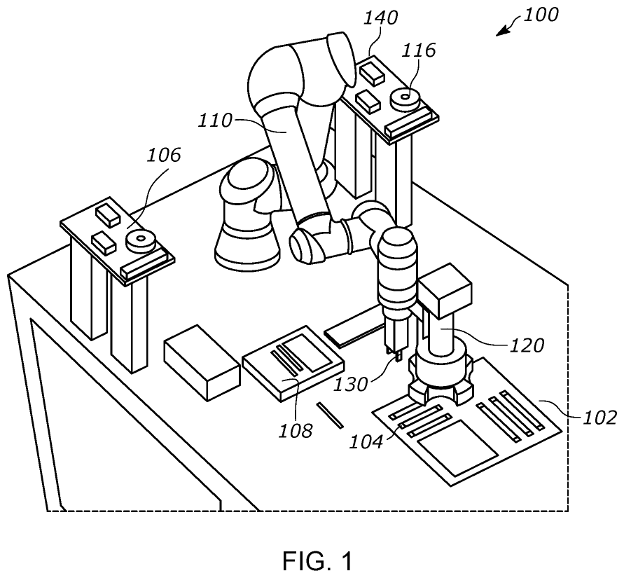

Referring now to FIG. 1, a work station 100 illustrates an embodiment appropriate for manufacturing a computer system including a printed circuit board (PCB) 102 appropriate for a server board on the computer system. For example, work station 100 may be appropriate for pick and place (PnP) manufacturing typically performed by humans. Embodiments herein, however, enable a collaborative robot 110 to work with a human to efficiently prepare server boards and computer systems. Server board 102 is shown including a plurality of dual inline memory module (DIMM) sockets 104 configured to receive memory modules. Embodiments herein enable a collaborative robot to place the sockets on the server board and secure the sockets as well as remove the sockets when necessary.

In FIG. 1, the work station 100 further includes a tray 106 for holding tools and attachment components for enabling collaborative robot 110 to insert different computer components, such as a plurality of sockets 108 ready for installation, onto server board 102 by collaborative robot 110. Work station 100 further illustrates tray 140 which may hold a plurality of memory modules 116 for installation onto server board 102. Memory modules 116 may include synchronous dynamic random access memory (SDRAM), double data rate (DDR) memory such as DDR4, DDR5 and DDR6 as will be appreciated by those of skill in the art.

Collaborative robot 110 is illustrated operatively coupled to camera 120. In one or more embodiments, collaborative robot 110 may be configured with a 850 mm reach equipped with a force torque sensor to prevent damage to server board 102 from over pressing. Collaborative robot 110 may further be configured with a 5 kg payload. In one embodiment, collaborative robot may be approximately three feet wide and four feet long. The collaborative robot 110 is further shown having effector end 130 that is configured to be able to use tools and attachments, such as screws, from tray 106 and insert different components onto server board 102. Work station 100 further illustrates tray 140 which may hold additional components for installation onto server board 102 such as memory modules.

Coupled to collaborative robot 110, is a camera 120 including a 64 Megapixel high resolution camera with a 57.6 ms capture speed. Camera 120 may be capable of imaging sockets and different components for insertion and removal from server board 102. In one embodiment, camera 120 is configured within a defined distance from effector end 130 to enable camera 120 to assist collaborative robot 110 in locating components and insert and remove the computer components into/onto the server board 102 based on alignment that may be detected using image data captured by the camera 120. For example, the image data of hardware to be secured to the server board 102 may be used to inspect the hardware for defects, and to determine coordinates of the respective pin/sockets of the hardware. As another example, the image data may include part numbers and/or serial numbers shown on the different hardware. The collaborative robot 110 may be instructed to align the coordinates of the pin/sockets of the hardware with the server board 102 based on known coordinates of the server board 102.

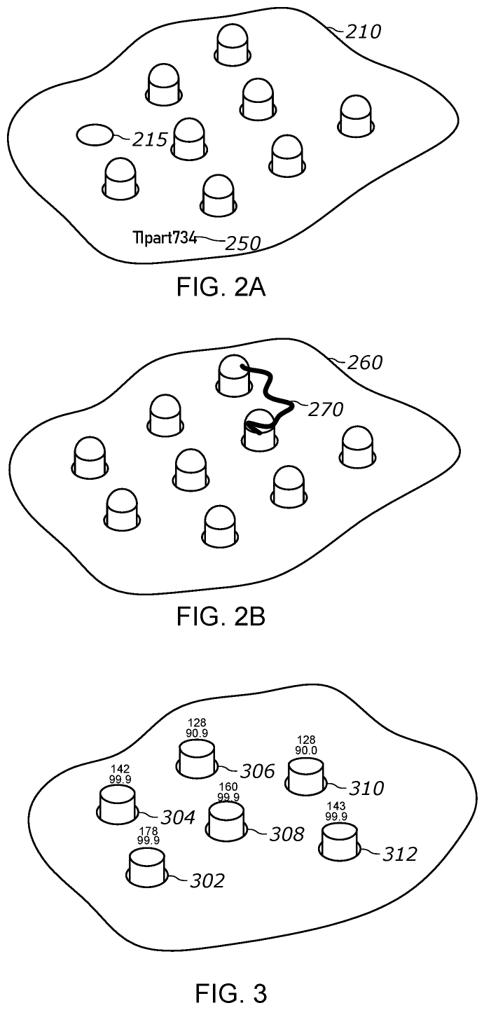

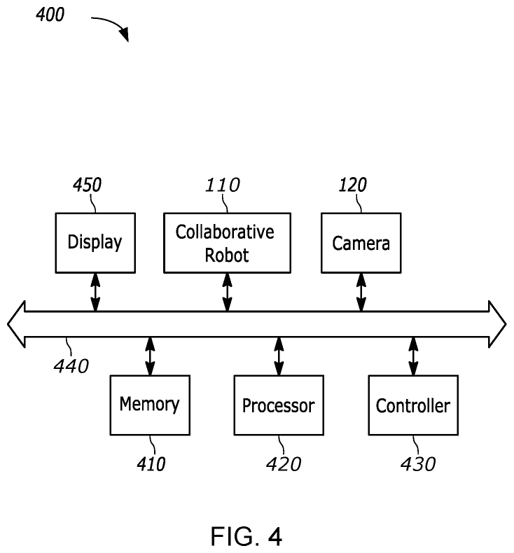

Referring now to FIG. 2A, a sample image of a socket 210 appropriate for a memory module have a plurality of pins illustrates a sunken pin 215. In one embodiment, camera 120 takes an image of a socket having a plurality of pins such as is shown in FIG. 2A. For example, sockets for memory modules may have 4000 pins. Memory modules with a plurality of pins may include DDR4 and DDR5 and the like. A processor, such as the processor 420 shown in FIG. 4, may analyze the image data captured by the camera 120 to detect defects such as sunken pins, for example, by comparing the image data to known pin configurations and determining when a pin in a known pin configuration for a given hardware is not shown in the image data for the hardware. FIG. 2A further illustrates a part number 250 which may be included as image data captured by camera 120 and analyzed by processor 420 to be compared, for example, with a known placement configuration on a server board.

Referring to FIG. 2B, sample image of socket 260 is illustrates another plurality of pins with foreign matter 270 that may be captured by camera 120 as a detected defect. Like a sunken pin, the image data to known configurations may be compared to known configurations by processor 420 to determine that the foreign matter necessitates checking socket 260. For example, if socket 260 is intended to receive DDR memory for testing purposes, foreign matter 270 may cause a short and prevent proper testing of a server board.

Referring to FIG. 3, another image using camera 120 is illustrated. In one embodiment, camera 120 includes two dimensional and three dimensional imaging capabilities. As shown, FIG. 3 includes multiple pins, 302, 304, 306, 308, 310 and 312, each with different heights and widths illustrated as measured and recorded using camera 120. In accordance with one or more embodiments, image data is received and processed to determine whether any of the heights and widths measured are outside of a known specifications. A processor, such as the processor 420 shown in FIG. 4, may analyze the image data captured by the camera 120 to detect defects such as sunken pins, for example, by comparing the image data to known pin configurations and determining when pin in a known pin configuration for a given hardware is not shown in the image data for the hardware. When the image data shows the pin configuration of a known pin configuration for the hardware represented by the image data, there may be no defects, and the hardware may be secured to a circuit board.

Referring now to FIG. 4, an embodiment is directed to a system and apparatus for manufacturing a computer system. As shown system 400 illustrates a memory 410, a processor 420, and controller 430 (e.g., including one or more processors) coupled to bus 440. Also shown coupled to bus 440 are display 450, collaborative robot 110 and camera 120. As described above, camera 120 may be operatively coupled to collaborative robot 110 to enable a human work alongside collaborative robot 110. In one or more embodiments, processor 420 receives image data such image data shown in FIGS. 2 and 3 that may be intended for server board 102. In one embodiment, the image data collected by camera 120 may enable processor 420 to determine, based on the image data, a coordinate location for one or more components intended for server board 102. Further, processor 420 may be configured to direct collaborative robot 110 to secure components to server board 102 using end effector 130 based on the image data. Thus, collaborative robot 110 with camera 120 may operate alongside a human, to manufacture a computer system with server board 102 based on received image data.

In one embodiment, the processor 420 directs collaborative robot 110 to secure components on server 102 based on received image data wherein the components are from a plurality of vendors. For example as shown in FIG. 1, different trays 106 and 140 may hold different components for insertion into server board 102. Camera 120, in one embodiment, may include character recognition to read the different component identifiers, such as QR codes and serial numbers to enable processor 420 and memory 410 to compare with known identifiers to be able to insert components in predetermined locations.

Part of the manufacturing process also includes inspecting components to be inserted on server board 102. Thus, one embodiment includes directing collaborative robot 110 to inspect components using camera 120, wherein the components include semiconductor memory sockets having stored pin configuration in the memory. Thus, if the socket shown in FIG. 3 is compared with a stored pin configuration, an AND operation or other comparison may be made to determine whether any of the heights and widths recorded by camera 120 are outside of a normal tolerance. Thus, camera 120 may inspect socket components for pin quality defects. For this purpose camera 120 may be configured with a pixel resolution of at least 64 megapixels with 0.0025 mm per pixel and three dimensional capabilities.

After inspecting sockets and other components for quality control, in one embodiment, processor 420 directs collaborative robot 110 to insert a plurality of sockets into server board 102 using end effector 130. For example, the sockets may be semiconductor duel in-line memory module (DIMM) sockets. Using the tools and attachment components, end effector 130 may be configured to install the sockets.

Next, in one embodiment, processor 420 may direct the collaborative robot 110 to lift and insert a semiconductor in-line memory module into each socket, each socket configured to hold dual in-line memory modules such as DDR4, DDR5 and the like.

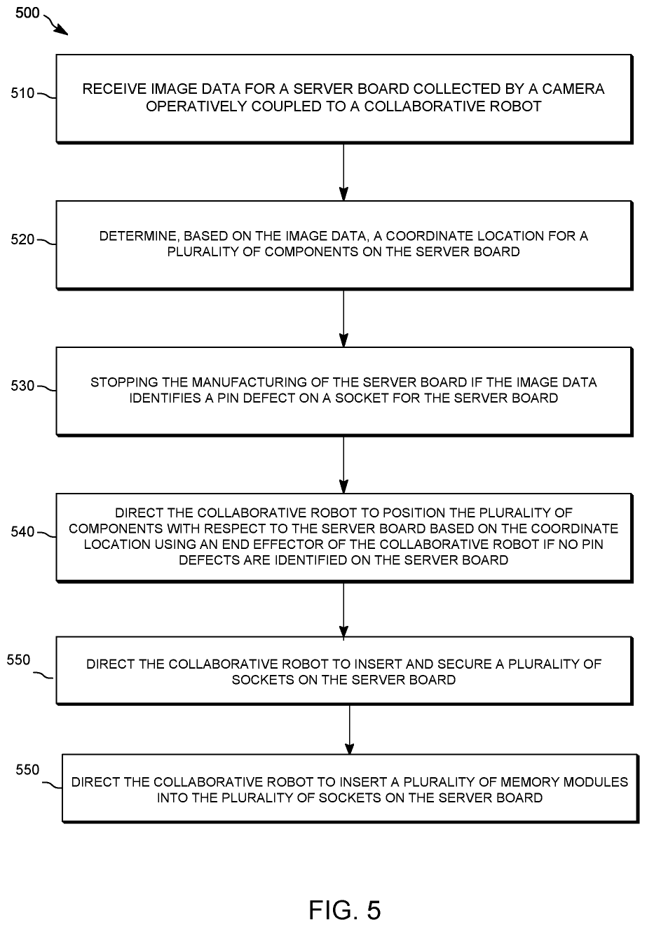

Referring now to FIG. 5, a flow diagram illustrates a method 500 for manufacturing a server board for a computer system in accordance with an embodiment. As shown, block 510 provides for receiving image data for a server board collected by a camera operatively connected to a collaborative robot. For example as shown in FIG. 4, processor 420 may direct collaborative robot 110 with camera 120 operatively coupled to collaborative robot 110 to image components shown in FIG. 1 for installation into server board 102. The image data is then received by processor 420 and may be displayed on display 450.

Block 520 provides for determining, based on the image data, a coordinate location for a plurality of components on the server board. For example, once processor 420 receives image data taken by camera 120, a coordinate location on server board 102 may be determined for a plurality of components on server board 102. The plurality of components may be sockets, such as DIMM sockets 104 and 108, memory components 116, and the like. In one embodiment, the plurality of components includes a plurality of pins for receiving memory modules. For example, in one embodiment, camera 120 is configured to make sure that memory modules are seated properly on server board 102 without any sunken pins. Memory modules may include modules with, for example 4000 pins that are micron sized and difficult for a human to inspect. The coordinate locations may be based on known configurations of the hardware being inspected. When the pins/sockets of the known hardware are identified and inspected for defects (e.g., by comparing the image data to the known configuration), and when the expected pins/sockets are present and not defective, the robot may align the pins/sockets with the server board to secure the hardware to the server board.

Block 530 provides for preventing the manufacturing of the server board if the image data identifies a pin defect on a socket for the server board. For example, as described above, FIG. 3 illustrates using camera 120 to take three dimensional images to identify a height and width of micron-sized pins on server board 102. If a server board has a memory module with sunken pins, the server board may be discarded or the memory module may need to be removed or the like, preventing the robot from securing the hardware to the server board. To determine whether there are sunken pins, in one embodiment, a stored map of the pins on a socket for a memory module may be compared with the three dimensional imaging of the pins along with a stored tolerance of height and width of the pins. If a pin is determined to be damaged or sunken, for example, a pin that is below a height required, a defect would be detected.

Block 540 provides for directing the collaborative robot to position the plurality of components with respect to the server board based on the coordinate location using an end effector of the collaborative robot if no pin defects are identified on the server board. For example, if no sunken pin defects are found using camera 120, in one embodiment, manufacturing is continued and collaborative robot 110 then continues to position different components such as sockets 108 and memory modules 116 onto server board 102 based on coordinate locations determined by camera 120. As described above, collaborative robot 110 has a reach to enable different trays 106 and 140, for example to be within reach. Thus, effector 130 may use different tools and attachment components to build server board 102 once it is determined that no sunken pins are present.

Block 550 provides for directing the collaborative robot to insert and secure a plurality of sockets onto the server board. For example, as shown in FIG. 1, server board 102 includes sockets 104 that were placed using collaborative robot 110 by having effector 130 use tools and screws.

Block 560 provides for directing the collaborative robot to insert a plurality of memory modules into the plurality of sockets on the server board. For example, as shown in FIG. 1, memory modules 116, which may be SDRAM, DDR type memory modules may be lifted using effector 130 and installed into server board 102. In one embodiment, the memory modules 116 may be installed for testing purposes and removed to enable server board to be transported as a computer system. In one embodiment, the different components are installed using tools and attachments to secure the plurality of components on the server board.

Another embodiment is directed to system for a collaborative robot that includes an end effector coupled to the collaborative robot, a camera system operatively coupled to the collaborative robot, the camera system configured to collect image data of a plurality of components intended for manufacturing a computer system. For example, as shown in FIG. 4, a system may include collaborative robot 110, camera 120 coupled to a bus 440 to enable manufacture a computer system including a printed circuit board (PCB), a plurality of components including at least a plurality of sockets such as sockets 104 and 108 shown in FIG. 1, and a plurality of dual in-line memory modules (DIMM), such as memory modules 116, a plurality of attachment components placed by a plurality of tools for use by the end effector, such as screws and tools shown in work station 100, and a communication interface such as bus 440 coupled to display 450 to enable interaction with a human, for example, and processing circuitry such as processor 420 coupled to the collaborative robot, the communication interface and processing circuitry configured to receive directions for manufacturing the computer system using the end effector and camera system. In one embodiment, communication interface includes controller 430 and bus 440 wherein controller 430 is operated by a human to control collaborative robot 110 and camera 120 to perform PnP actions.

In one embodiment processor 420 determines, based on the collected image data, a coordinate location for the plurality of components, and secures the plurality of components to the PCB using the end effector of the collaborative robot 110 based on the image data collected by camera 120. Further, processor 420 may perform model differentiation based on the collected image data via character reading by the camera system to identify components among the plurality of components. For example, camera system may include character recognition, such as QR code identification or the like to identify diverse components from a plurality of different vendors to enable collaborative robot to combine different components a same server board 102. In one embodiment, as shown in FIG. 2A, the camera system identifies part numbers to differentiate and identify diverse components to enable collaborative robot to manufacture server board 102.

In one embodiment, controller 430 also directs inspection of the plurality of components, for socket pin defects with the camera system 120 wherein the plurality of components may include pins in a socket and the camera 120 uses three dimensional imaging performed by the camera system. For example, as shown on FIG. 3, heights and widths of a plurality of pins may by compared with known placements of pins stored in memory 410 and available for comparison. For example processor 420 may compare stored socket pin locations to identify sunken pin locations based on three dimensional imaging performed by camera system 120 and a comparison to stored socket pin locations.

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” “an example embodiment,” “example implementation,” etc., indicate that the embodiment or implementation described may include a particular feature, structure, or characteristic, but every embodiment or implementation may not necessarily include the particular feature, structure, or characteristic. Moreover, such phrases are not necessarily referring to the same embodiment or implementation. Further, when a particular feature, structure, or characteristic is described in connection with an embodiment or implementation, one skilled in the art will recognize such feature, structure, or characteristic in connection with other embodiments or implementations whether or not explicitly described. For example, various features, aspects, and actions described above with respect to an autonomous parking maneuver are applicable to various other autonomous maneuvers and must be interpreted accordingly.

Implementations of the systems, apparatuses, devices, and methods disclosed herein may comprise or utilize one or more devices that include hardware, such as, for example, one or more processors and system memory, as discussed herein. An implementation of the devices, systems, and methods disclosed herein may communicate over a computer network. A “network” is defined as one or more data links that enable the transport of electronic data between computer systems and/or modules and/or other electronic devices. When information is transferred or provided over a network or another communications connection (either hardwired, wireless, or any combination of hardwired or wireless) to a computer, the computer properly views the connection as a transmission medium. Transmission media can include a network and/or data links, which can be used to carry desired program code means in the form of computer-executable instructions or data structures and which can be accessed by a general purpose or special purpose computer. Combinations of the above should also be included within the scope of non-transitory computer-readable media.

Computer-executable instructions comprise, for example, instructions and data which, when executed at a processor, cause the processor to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

A memory device can include any one memory element or a combination of volatile memory elements (e.g., random access memory (RAM, such as DRAM, SRAM, SDRAM, etc.)) and non-volatile memory elements (e.g., ROM, hard drive, tape, CDROM, etc.). Moreover, the memory device may incorporate electronic, magnetic, optical, and/or other types of storage media. In the context of this document, a “non-transitory computer-readable medium” can be, for example but not limited to, an electronic, magnetic, optical, electromagnetic, infrared, or semiconductor system, apparatus, or device. More specific examples (a non-exhaustive list) of the computer-readable medium would include the following: a portable computer diskette (magnetic), a random-access memory (RAM) (electronic), a read-only memory (ROM) (electronic), an erasable programmable read-only memory (EPROM, EEPROM, or Flash memory) (electronic), and a portable compact disc read-only memory (CD ROM) (optical). Note that the computer-readable medium could even be paper or another suitable medium upon which the program is printed, since the program can be electronically captured, for instance, via optical scanning of the paper or other medium, then compiled, interpreted or otherwise processed in a suitable manner if necessary, and then stored in a computer memory.

Those skilled in the art will appreciate that the present disclosure may be practiced in network computing environments with many types of computer system configurations, including in-dash vehicle computers, personal computers, desktop computers, laptop computers, message processors, nomadic devices, multi-processor systems, microprocessor-based or programmable consumer electronics, network PCs, minicomputers, mainframe computers, mobile telephones, PDAs, tablets, pagers, routers, switches, various storage devices, and the like. The disclosure may also be practiced in distributed system environments where local and remote computer systems, which are linked (either by hardwired data links, wireless data links, or by any combination of hardwired and wireless data links) through a network, both perform tasks. In a distributed system environment, program modules may be located in both the local and remote memory storage devices.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description, and claims refer to particular system components. As one skilled in the art will appreciate, components may be referred to by different names. This document does not intend to distinguish between components that differ in name, but not function.

At least some embodiments of the present disclosure have been directed to computer program products comprising such logic (e.g., in the form of software) stored on any computer-usable medium. Such software, when executed in one or more data processing devices, causes a device to operate as described herein.

While various embodiments of the present disclosure have been described above, it should be understood that they have been presented by way of example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described example embodiments but should be defined only in accordance with the following claims and their equivalents. The foregoing description has been presented for the purposes of illustration and description. It is not intended to be exhaustive or to limit the present disclosure to the precise form disclosed. Many modifications and variations are possible in light of the above teaching. Further, it should be noted that any or all of the aforementioned alternate implementations may be used in any combination desired to form additional hybrid implementations of the present disclosure. For example, any of the functionality described with respect to a particular device or component may be performed by another device or component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

Various examples are provided herein.

Example 1 may include an apparatus for manufacturing a computer system, the apparatus comprising: a collaborative robot including an end effector; a camera operatively coupled to the collaborative robot; a memory coupled to the collaborative robot; and processing circuitry coupled to the memory, the processing circuitry configured to: receive image data of a computer component, the image data collected by the camera operatively coupled to the collaborative robot; determine, based on the image data, a coordinate location for the computer component; and direct the collaborative robot to secure the computer component to a printed circuit board (PCB) using the end effector based on the coordinate location.

Example 2 may include the apparatus for manufacturing of example 1 wherein the collaborative robot in combination with the camera is configured to manufacture the computer system by securing the computer component to the PCB, the computer system including the PCB.

Example 3 may include the apparatus for manufacturing of example 1 wherein the processing circuitry is further configured to: direct the collaborative robot to secure pins of the computer component to the PCB based on the image data, the PCB configured as a server board and the computer component being one of a plurality vendor-sourced computer components that the collaborative robot is configured to secure to the PCB.

Example 4 may include the apparatus for manufacturing of example 1, wherein the computer component is a semiconductor memory socket component having pin configuration stored in the memory, and wherein to determine the coordinate location for the computer component comprises to determine the coordinate location based on the pin configuration.

Example 5 may include the apparatus for manufacturing of example 4 wherein the processing circuitry is further configured to: detect a defect in a pin, the camera having a pixel resolution of at least 64 megapixels with 0.0025 mm per pixel, and wherein the image data comprise three dimensional image data.

Example 6 may include the apparatus for manufacturing of example 1 wherein the processing circuitry is further configured to: direct the collaborative robot to insert a plurality of sockets into the PCB using the end effector, the sockets configured to receive a semiconductor in-line memory module.

Example 7 may include the apparatus for manufacturing of example 6 wherein the processing circuitry is further configured to: direct the collaborative robot to lift and insert the semiconductor in-line memory module into each of the sockets, each of the sockets configured to hold dual in-line memory modules (DIMM).

Example 8 may include the apparatus for manufacturing of example 1 wherein the processing circuitry is further configured to: direct inspection of the computer component for socket pin defects based on the image data, the computer component being a socket comprised of a plurality of pins.

Example 9 may include a method for manufacturing a server board for a computer system comprising: receiving, by processing circuitry of a device associated with a collaborative robot, image data for the server board collected by a camera operatively connected to the collaborative robot; determining, by the processing circuitry, based on the image data, a coordinate location for a plurality of computer components on the server board; preventing, by the processing circuitry, operation of the collaborative robot causing the manufacturing of the server board when the image data are indicative of a pin defect on a socket for the server board; and directing, by the processing circuitry, the collaborative robot to position the plurality of computer components with respect to the server board based on the coordinate location using an end effector of the collaborative robot when no pin defects are indicated on the server board by the image data.

Example 10 may include the method for manufacturing of example 9 wherein the directing the collaborative robot to position the plurality of computer components on the server board further includes: directing the collaborative robot to insert and secure a plurality of sockets to the server board; and directing the collaborative robot to insert a plurality of memory modules into the plurality of sockets.

Example 11 may include the method for manufacturing of example 9 wherein the directing the collaborative robot to position the plurality of computer components on the server board further includes: directing an attachment to the collaborative robot to secure the plurality of computer components to the server board.

Example 12 may include the method for manufacturing of example 9 further comprising: inspecting socket pin quality for pin defects based on a received socket pin configuration.

Example 13 may include the method for manufacturing of example 12 wherein inspecting the socket pin quality further comprising: comparing the received pin configuration to known socket pin locations; and identifying sunken pin locations based on three dimensional imaging performed by the camera based on the comparing.

Example 14 may include the method for manufacturing of example 12 wherein the camera has a pixel resolution of at least 64 megapixels with 0.0025 mm per pixel, and wherein the image data comprise three dimensional image data.

Example 15 may include a system for a collaborative robot comprising: an end effector coupled to the collaborative robot; a camera system operatively coupled to the collaborative robot, the camera system configured to collect image data of a plurality of computer components intended for manufacturing a computer system, the computer system including: a printed circuit board (PCB); the plurality of computer components including at least a plurality of sockets; a plurality of dual in-line memory modules (DIMM); and a plurality of attachment components placed by a plurality of tools for use by the end effector; and a communication interface and processing circuitry coupled to the collaborative robot, the communication interface and processing circuitry configured to receive directions for manufacturing the computer system using the end effector based on the image data.

Example 16 may include the system for the collaborative robot of example 15 wherein the processing circuitry is configured to determine, based on the image data, a coordinate location for the plurality of computer components, and cause the collaborative robot to secure the plurality of computer components to the PCB using the end effector based on the coordinate location.

Example 17 may include the system for the collaborative robot of example 15 wherein the processing circuitry is configured to perform model differentiation based on the image data via character reading, the model differentiation associated with identifying a component among the plurality of computer components.

Example 18 may include the system for the collaborative robot of example 15 wherein the processing circuitry is configured to direct inspection of the plurality of computer components for socket pin defects, wherein the plurality of computer components includes a socket comprised of a plurality of pins based on three dimensional imaging performed by the camera system.

Example 19 may include the system for the collaborative robot of example 15 wherein the processing circuitry is further configured to identify sunken pin locations based on three dimensional imaging performed by the camera system.

Example 20 may include the system for the collaborative robot of example 15 wherein the camera system has a pixel resolution of at least 64 megapixels with 0.0025 mm per pixel, and wherein the image data comprise three dimensional image data.

Example 21 may include one or more non-transitory computer-readable media comprising instructions to cause an electronic device, upon execution of the instructions by one or more processors of the electronic device, to perform one or more elements of a method described in or related to any of examples 1-20, or any other method or process described herein

Example 22 may include an apparatus comprising logic, modules, and/or circuitry to perform one or more elements of a method described in or related to any of examples 1-21, or any other method or process described herein.

Example 23 may include a method, technique, or process as described in or related to any of examples 1-21, or portions or parts thereof.

### Terminology

For the purposes of the present document, the following terms and definitions are applicable to the examples and embodiments discussed herein.

The term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” as used herein refers to, is part of, or includes circuitry capable of sequentially and automatically carrying out a sequence of arithmetic or logical operations, or recording, storing, and/or transferring digital data. Processing circuitry may include one or more processing cores to execute instructions and one or more memory structures to store program and data information. The term “processor circuitry” may refer to one or more application processors, one or more baseband processors, a physical central processing unit (CPU), a single-core processor, a dual-core processor, a triple-core processor, a quad-core processor, and/or any other device capable of executing or otherwise operating computer-executable instructions, such as program code, software modules, and/or functional processes. Processing circuitry may include more hardware accelerators, which may be microprocessors, programmable processing devices, or the like. The one or more hardware accelerators may include, for example, computer vision (CV) and/or deep learning (DL) accelerators. The terms “application circuitry” and/or “baseband circuitry” may be considered synonymous to, and may be referred to as, “processor circuitry.”

The term “interface circuitry” as used herein refers to, is part of, or includes circuitry that enables the exchange of information between two or more components or devices. The term “interface circuitry” may refer to one or more hardware interfaces, for example, buses, I/O interfaces, peripheral component interfaces, network interface cards, and/or the like.

The term “computer system” as used herein refers to any type interconnected electronic devices, computer devices, or components thereof. Additionally, the term “computer system” and/or “system” may refer to various components of a computer that are communicatively coupled with one another. Furthermore, the term “computer system” and/or “system” may refer to multiple computer devices and/or multiple computing systems that are communicatively coupled with one another and configured to share computing and/or networking resources.

The term “appliance,” “computer appliance,” or the like, as used herein refers to a computer device or computer system with program code (e.g., software or firmware) that is specifically designed to provide a specific computing resource. A “virtual appliance” is a virtual machine image to be implemented by a hypervisor-equipped device that virtualizes or emulates a computer appliance or otherwise is dedicated to provide a specific computing resource.

The term “resource” as used herein refers to a physical or virtual device, a physical or virtual component within a computing environment, and/or a physical or virtual component within a particular device, such as computer devices, mechanical devices, memory space, processor/CPU time, processor/CPU usage, processor and accelerator loads, hardware time or usage, electrical power, input/output operations, ports or network sockets, channel/link allocation, throughput, memory usage, storage, network, database and applications, workload units, and/or the like. A “hardware resource” may refer to compute, storage, and/or network resources provided by physical hardware element(s). A “virtualized resource” may refer to compute, storage, and/or network resources provided by virtualization infrastructure to an application, device, system, etc. The term “network resource” or “communication resource” may refer to resources that are accessible by computer devices/systems via a communications network. The term “system resources” may refer to any kind of shared entities to provide services, and may include computing and/or network resources. System resources may be considered as a set of coherent functions, network data objects or services, accessible through a server where such system resources reside on a single host or multiple hosts and are clearly identifiable.

The terms “instantiate,” “instantiation,” and the like as used herein refers to the creation of an instance. An “instance” also refers to a concrete occurrence of an object, which may occur, for example, during execution of program code.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

That which is claimed is:

1. An apparatus for manufacturing a computer system, the apparatus comprising:
a collaborative robot including an end effector;
a camera operatively coupled to the collaborative robot;
a memory coupled to the collaborative robot; and
processing circuitry coupled to the memory, the processing circuitry configured to:
receive image data of a computer component, the image data collected by the camera operatively coupled to the collaborative robot;
determine, based on the image data, a coordinate location for the computer component; and
direct the collaborative robot to secure the computer component to a printed circuit board (PCB) using the end effector based on the coordinate location.

2. The apparatus for manufacturing of claim 1 wherein the collaborative robot in combination with the camera is configured to manufacture the computer system by securing the computer component to the PCB, the computer system including the PCB.

3. The apparatus for manufacturing of claim 1 wherein the processing circuitry is further configured to:
direct the collaborative robot to secure pins of the computer component to the PCB based on the image data, the PCB configured as a server board and the computer component being one of a plurality vendor-sourced computer components that the collaborative robot is configured to secure to the PCB.

4. The apparatus for manufacturing of claim 1, wherein the computer component is a semiconductor memory socket component having pin configuration stored in the memory, and wherein to determine the coordinate location for the computer component comprises to determine the coordinate location based on the pin configuration.

5. The apparatus for manufacturing of claim 4 wherein the processing circuitry is further configured to:
detect a defect in a pin, the camera having a pixel resolution of at least 64 megapixels with 0.0025 mm per pixel, and wherein the image data comprise three dimensional image data.

6. The apparatus for manufacturing of claim 1 wherein the processing circuitry is further configured to:
direct the collaborative robot to insert a plurality of sockets into the PCB using the end effector, the sockets configured to receive a semiconductor in-line memory module.

7. The apparatus for manufacturing of claim 6 wherein the processing circuitry is further configured to:
direct the collaborative robot to lift and insert the semiconductor in-line memory module into each of the sockets, each of the sockets configured to hold dual in-line memory modules (DIMM).

8. The apparatus for manufacturing of claim 1 wherein the processing circuitry is further configured to:
direct inspection of the computer component for socket pin defects based on the image data, the computer component being a socket comprised of a plurality of pins.

9. A method for manufacturing a server board for a computer system comprising:
receiving, by processing circuitry of a device associated with a collaborative robot, image data for the server board collected by a camera operatively connected to the collaborative robot;
determining, by the processing circuitry, based on the image data, a coordinate location for a plurality of computer components on the server board;
preventing, by the processing circuitry, operation of the collaborative robot causing the manufacturing of the server board when the image data are indicative of a pin defect on a socket for the server board; and
directing, by the processing circuitry, the collaborative robot to position the plurality of computer components with respect to the server board based on the coordinate location using an end effector of the collaborative robot when no pin defects are indicated on the server board by the image data.

10. The method for manufacturing of claim 9 wherein the directing the collaborative robot to position the plurality of computer components on the server board further includes:
directing the collaborative robot to insert and secure a plurality of sockets to the server board; and
directing the collaborative robot to insert a plurality of memory modules into the plurality of sockets.

11. The method for manufacturing of claim 9 wherein the directing the collaborative robot to position the plurality of computer components on the server board further includes:
directing an attachment to the collaborative robot to secure the plurality of computer components to the server board.

12. The method for manufacturing of claim 9 further comprising:
inspecting socket pin quality for pin defects based on a received socket pin configuration.

13. The method for manufacturing of claim 12 wherein inspecting the socket pin quality further comprising:
comparing the received pin configuration to known socket pin locations; and
identifying sunken pin locations based on three dimensional imaging performed by the camera based on the comparing.

14. The method for manufacturing of claim 12 wherein the camera has a pixel resolution of at least 64 megapixels with 0.0025 mm per pixel, and wherein the image data comprise three dimensional image data.

15. A system for a collaborative robot comprising:
an end effector coupled to the collaborative robot;
a camera system operatively coupled to the collaborative robot, the camera system configured to collect image data of a plurality of computer components intended for manufacturing a computer system, the computer system including:
a printed circuit board (PCB);
the plurality of computer components including at least a plurality of sockets;
a plurality of dual in-line memory modules (DIMM); and
a plurality of attachment components placed by a plurality of tools for use by the end effector; and
a communication interface and processing circuitry coupled to the collaborative robot, the communication interface and processing circuitry configured to receive directions for manufacturing the computer system using the end effector based on the image data.

16. The system for the collaborative robot of claim 15 wherein the processing circuitry is configured to determine, based on the image data, a coordinate location for the plurality of computer components, and cause the collaborative robot to secure the plurality of computer components to the PCB using the end effector based on the coordinate location.

17. The system for the collaborative robot of claim 15 wherein the processing circuitry is configured to perform model differentiation based on the image data via character reading, the model differentiation associated with identifying a component among the plurality of computer components.

18. The system for the collaborative robot of claim 15 wherein the processing circuitry is configured to direct inspection of the plurality of computer components for socket pin defects, wherein the plurality of computer components includes a socket comprised of a plurality of pins based on three dimensional imaging performed by the camera system.

19. The system for the collaborative robot of claim 15 wherein the processing circuitry is further configured to identify sunken pin locations based on three dimensional imaging performed by the camera system.

20. The system for the collaborative robot of claim 15 wherein the camera system has a pixel resolution of at least 64 megapixels with 0.0025 mm per pixel, and wherein the image data comprise three dimensional image data.
